(19) United States
(12) Patent Application Publication
(10) Pub. No.: US 2016/0164039 A1
(43) Pub. Date: Jun. 9, 2016

(54) ORGANIC LIGHT EMITTING DEVICE AND DISPLAY DEVICE HAVING THE SAME

(71) Applicant: Samsung Display Co., Ltd., Yongin-city (KR)

(72) Inventor: Jahyun IM, Yongin-si (KR)

(21) Appl. No.: 14/799,978

(22) Filed: Jul. 15, 2015

(30) Foreign Application Priority Data
Dec. 8, 2014 (KR) 10-2014-0174807

(51) Int. Cl. H01L 51/52; H01L 27/32; H01L 51/00; H01L 51/50

(52) U.S. Cl. CPC H01L 51/5271; H01L 51/5253; H01L 51/5072; H01L 27/3244; H01L 51/5256; H01L 51/5218; H01L 51/5234; H01L 27/3248; H01L 51/0058; H01L 2251/301; H01L 51/0077; H01L 2251/305

(57) ABSTRACT

Provided is an organic light emitting device including a first electrode, a hole transport region provided on the first electrode, a light emission layer provided on the hole transport region, an electron transport region provided on the light emission layer, a second electrode provided on the electron transport region, and an organic capping layer provided on the second electrode. The organic capping layer includes an anthracene-based compound. The organic capping layer may include a compound expressed by Chemical Formula 1 below.

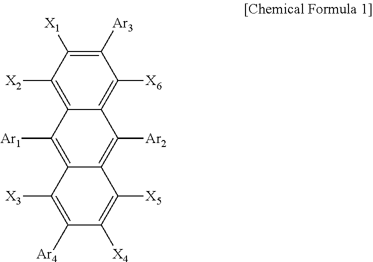

### CROSS-REFERENCE TO RELATED APPLICATION

This application claims priority from and the benefit of Korean Patent Application No. 10-2014-0174807, filed on Dec. 8, 2014, which is hereby incorporated by reference for all purposes as if fully set forth herein.

### BACKGROUND

1. Field

Exemplary embodiments relate to an organic light emitting device and a display device having the same.

2. Discussion of the Background

Flat display devices may be mainly classified into a luminescent type and a photoreceptive type. Examples of the luminescent type include a flat cathode ray tube, a plasma display panel, and an organic light emitting display (OLED). An organic light emitting display may have a wide viewing angle, high contrast, and a fast response time, similar to a spontaneous-luminescent-type display.

Accordingly, an organic light emitting display may be applicable to display devices for mobile equipment such as a digital camera, a video camera, a camcorder, a personal digital assistant, a smart phone, an ultra-slim laptop, a tablet personal computer, a flexible display device, or heavy electronic or electrical devices such as an ultrathin-type television.

Organic light emitting displays express colors based on the principle that holes and electrons, which are injected to first and second electrodes, are recombined in a light emission layer to emit light, and the light is emitted when excitons, which are formed by combination of the injected holes and electrons, fall from an exited state to a ground state.

The above information disclosed in this Background section is only for enhancement of understanding of the background of the present disclosure, and, therefore, it may contain information that does not form the prior art that is already known in this country to a person of ordinary skill in the art.

### SUMMARY

Exemplary embodiments provide a display device having high efficiency and long life.

Additional aspects will be set forth in the detailed description which follows, and, in part, will be apparent from the disclosure, or may be learned by practice of the present disclosure.

According to one or more exemplary embodiments of the present disclosure, organic light emitting devices may include a first electrode, a hole transport region provided on the first electrode, a light emission layer provided on the hole transport region, an electron transport region provided on the light emission layer, a second electrode provided on the electron transport region, and an organic capping layer provided on the second electrode. The organic capping layer may include an anthracene-based compound.

In other exemplary embodiments of the present disclosure, display devices may include a plurality of pixels. At least one of the pixels may include a first electrode, a hole transport region provided on the first electrode, a light emission layer provided on the hole transport region, an electron transport region provided on the light emission layer, a second electrode provided on the electron transport region, and an organic capping layer provided on the second electrode. The organic capping layer may include an anthracene-based compound.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the present disclosure, and are incorporated in and constitute a part of this specification, illustrate exemplary embodiments of the present disclosure, and, together with the description, serve to explain principles of the present disclosure.

FIG. 1 is a sectional view schematically illustrating an organic light emitting device according to an exemplary embodiment.

FIG. 2 is a sectional view schematically illustrating an organic light emitting device according to an exemplary embodiment.

FIG. 3 is a perspective view schematically illustrating a display device according to an exemplary embodiment.

FIG. 4 is a circuit diagram of one of pixels included in a display device according to an exemplary embodiment.

FIG. 5 is a plan view illustrating one of pixels included in a display device according to an exemplary embodiment.

FIG. 6 is a schematic sectional view taken along line I-I′ in FIG. 5.

FIG. 7 is a schematic sectional view taken along line I-I′ in FIG. 5.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular exemplary embodiments and is not intended to be limiting. As used herein, the singular forms, “a,” “an,” and “the” are intended to include the plural forms as well, unless the context clearly indicates otherwise. Moreover, the terms “comprises, ““comprising, ““includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

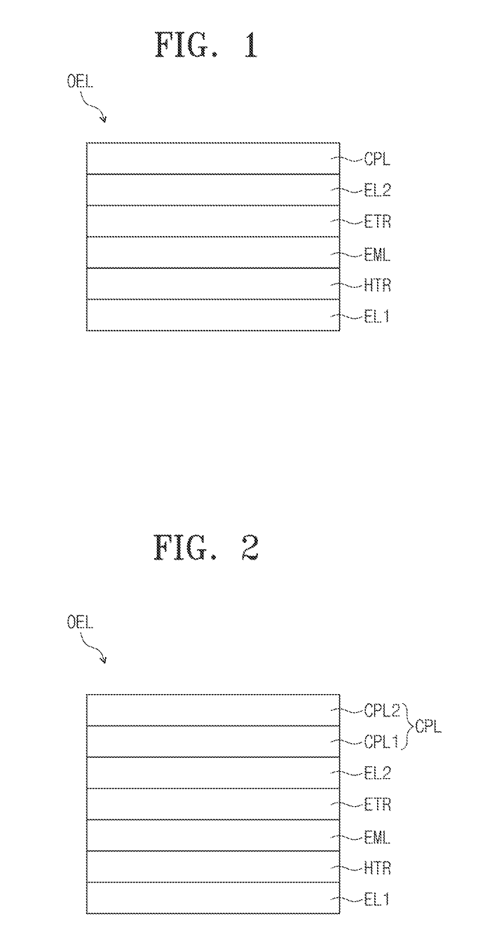

FIG. 1 is a sectional view schematically illustrating an organic light emitting device according to an exemplary embodiment.

Referring to FIG. 1, organic light emitting device OEL may include first electrode EL1, hole transport region HTR, light emission layer EML, electron transport region ETR, second electrode EL2, and organic capping layer CPL.

First electrode EL1 is conductive and may be a pixel electrode or anode, First electrode EL1 may be a transmissive electrode, a transflective electrode, or a reflective electrode. When first electrode EL1 is a transmissive electrode, first electrode EL1 may be made of transparent metal oxide such as indium tin oxide (ITO), indium zinc oxide (IZO), zinc oxide (ZnO), or indium tin zinc oxide (ITZO). When first electrode EL1 is a transflective electrode or the reflective electrode, first electrode EL1 may include Ag, Mg, Al, Pt, Pd, Au, Ni, Nd, Ir, Cr, or a mixture thereof.

An organic layer may be disposed on the first electrode EL1 and may include light emission layer EML. The organic layer may further include hole transport region HTR and electron transport region ETR.

Hole transport region HTR may be provided on the first electrode EL1. Hole transport region HTR may include at least one of a hole injection layer HIL, a hole transport layer HTL, a buffer layer, or an electron blocking layer.

Hole transport region HTR may have a single layer made of a single material, a single layer made of a plurality of different materials, or a multi-layered structure having a plurality layers made of a plurality of different materials. In exemplary embodiments, hole transport region HTR may have a single-layered structure made of a plurality of different materials, or a multi-layered structure which is sequentially stacked from the first electrode EL1, such as hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer, but is not limited thereto.

Hole transport region HTR may be provided using various methods such as vacuum deposition, spin coating, casting, Langmuir-Blodgett (LB), inkjet printing, laser printing, or laser induced thermal imaging (LITI).

According to one or more exemplary embodiments, when hole transport region HTR includes the hole injection layer HIL, hole transport region HTR may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris {N,-(2-naphthyl)-N-phenylamino}-triphenylamine (2TNATA), poly(3,4-ethylenedioxythiophene)/poly(4-styrenesulfonate) (PEDOT/PSS), polyaniline/dodecylbenzenesulfonic acid (PANI/DBSA), polyaniline/Camphor sulfonicacid (PANI/CSA), or (polyaniline)/poly(4-styrenesulfonate) (PANI/PSS), but is not limited thereto. Additionally, hole transport region HTR may include a carbazole derivative such as N-phenylcarbazole or polyvinylcarbazole, a fluorine derivative, a triphenylamine derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(1-naphthyl)-N,N′-diphenylbenzidine (NPB), or 4,4′-cyclohexylidene bis[N,N-bis(4-methylphenyl)benzenamine](TAPC), but is not limited thereto.

Hole transport region HTR may have a thickness of about 100 Å to about 10,000 Å, e.g., about 100 Å to about 1,000 Å. When hole transport region HTR includes both the hole injection layer HIL and the hole transport layer HTL, the hole injection layer HIL may have a thickness of about 100 Å to about 10,000 Å, e.g., about 100 Å to about 1,000 Å, and the hole transport layer HTL may have a thickness of about 50 Å to about 2,000 Å, e.g., about 100 Å to about 1,500 Å. When the thicknesses of hole transport region HTR, hole injection layer HIL, and hole transport layer HTL fall within the above ranges, respectively, satisfactory hole transport characteristics may be obtained without a substantial increase in driving voltage.

Hole transport region HTR may further include a charge generation material for improving conductivity, in addition to the aforementioned materials. The charge generation material may be homogeneously or non-homogeneously dispersed in hole transport region HTR. The charge generation material may be a p-dopant. The p-dopant may be, but is not limited to, one of a quinone derivative, a metal oxide, or a cyano group-containing compound. Non-restrictive examples of the p-dopant may include a quinone derivative such as tetracyanoquinodimethane (TCNQ) or 2,3,5,6-tetrafluoro-tetracyanoquinodimethane (F4-TCNQ), and a metal oxide such as tungsten oxide or molybdenum oxide, but are not limited thereto.

As mentioned above, hole transport region HTR may include at least one of a buffer layer or an electron blocking layer, in addition to the hole injection layer HIL and hole transport layer HTL. The buffer layer may compensate a resonance distance according to the wavelength of light emitted from light emission layer EML and thus serve to increase luminous efficiency. Materials included in hole transport region HTR may be used for materials included in the buffer layer. The electron blocking layer serves to prevent electrons from being injected from electron transport region ETR to hole transport region HTR.

Light emission layer EML is provided on hole transport region HTR. Light emission layer EML may have a single layer made of a single material, a single layer made of a plurality of different materials, or a multi-layered structure having a plurality layers made of a plurality of different materials.

Light emission layer EML may be provided using various methods such as vacuum deposition, spin coating, casting, Langmuir-Blodgett (LB), inkjet printing, laser printing, or laser induced thermal imaging (LITI).

Light emission layer EML may be made of generally available materials, e.g., materials emitting red light, green light, and blue light, and may include a fluorescent material or a phosphor. Also, light emission layer EML may include a host and a dopant.

The host may employ a material which is generally used, such as tris(8-hydroxyquinolino)aluminum (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN).

When light emission layer EML emits red light, light emission layer EML may include a fluorescent material containing (tris(dibenzoylmethanato)phenanthoroline europium) (PBD:Eu(DBM)3(Phen)) or perylene. When light emission layer EML emits red light, the dopant included in light emission layer EML may be selected from the group consisting of a metal complex and an organometallic complex, such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), and octaethylporphyrin platinum (PtOEP).

When light emission layer EML emits green light, light emission layer EML may include a fluorescent material containing tris(8-hydroxyquinolino)aluminum (Alq3). When light emission layer EML emits green light, the dopant included in light emission layer EML may be selected from the group consisting of a metal complex and an organometallic complex such as fac-tris(2-phenylpyridine)iridium (Ir(ppy)3).

When light emission layer EML emits blue light, light emission layer EML may include a fluorescent material containing any one selected from the group consisting of spiro-DPVBi, spiro-6P, distyryl-benzene (DSB), distyryl-arylene (DSA), a polyfluorene (PFO) based polymer, and a poly(p-phenylene vinylene) (PPV) based polymer. When light emission layer EML emits blue light, the dopant included in light emission layer EML may be selected from the group consisting of a metal complex and an organometallic complex such as (4,6-F2ppy)2Irpic.

Electron transport region ETR is provided on light emission layer EML. Electron transport region ETR may include, but is not limited to, at least one of a hole blocking layer, an electron transport layer, or an electron injection layer. In exemplary embodiments, electron transport region ETR may have a multi-layered structure which is sequentially stacked from light emission layer EML, such as electron transport layer/electron injection layer or hole blocking layer/electron transport layer/electron injection layer, or have a single-layered structure in which at least two of the above layers are mixed. However the present disclosure is not limited thereto.

Electron transport region ETR may be provided using various methods such as vacuum deposition, spin coating, casting, Langmuir-Blodgett (LB), inkjet printing, laser printing, or laser induced thermal imaging (LITI)

When electron transport region ETR includes the electron transport layer, electron transport region ETR may include tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), or mixtures thereof, but is not limited thereto. The electron transport layer may have a thickness of about 100 Å to about 1,000 Å, e.g., about 150 Å to about 500 Å. When the thickness of the electron transport layer falls within the above range, satisfactory electron transport characteristics may be obtained without a substantial increase in driving voltage.

When electron transport region ETR includes the electron injection layer, electron transport region ETR may use LiF, LiQ, Li₂O, BaO, NaCl, CsF, lanthanoide such as Yb, or a metal halide such as RbCl or RbI, but is not limited thereto. The electron injection layer may also be made of a mixture of an electron-transporting material and an insulating organo metal salt. The organo metal salt may have an energy band gap of about 4 eV or more than 4 eV. Specifically, the organo metal salt may include metal acetate, metal benzoate, metal acetoacetate, metal acetylacetonate, or metal stearate. The electron injection layer may have a thickness of about 1 Å to about 100 Å, e.g., about 3 Å to about 90 Å. When the thickness of the electron injection layer falls within the above range, satisfactory electron injection characteristics may be obtained without a substantial increase in driving voltage.

As mentioned above, electron transport region ETR may include the hole blocking layer. For example, the hole blocking layer may include at least one of 2,9-dimethyl-4,7-diphenyl-1,10-phenanthroline (BCP) or 4,7-diphenyl-1,10-phenanthroline (Bphen), but is not limited thereto. The hole blocking layer may have a thickness of about 20 Å to about 1,000 Å, e.g., about 30 Å to about 300 Å. When the thickness of the hole blocking layer falls within the above range, satisfactory hole blocking characteristics may be obtained without a substantial increase in driving voltage.

Second electrode EL2 is provided on the organic layer. Second electrode EL2 may be a common electrode or a cathode. Second electrode EL2 may be a transmissive electrode or a transflective electrode. When second electrode EL2 is the transmissive electrode, second electrode EL2 may include Li, Ca, LiF/Ca, LiF/Al, Al, Mg, BaF, Ba, Ag, or compounds or mixtures thereof (e.g., a mixture of Ag and Mg).

Second electrode EL2 may include an auxiliary electrode. The auxiliary electrode may include a film, and a transparent metal oxide on the film. Herein, the film may be formed in such a way that the above-described material is deposited to face light emission layer EML, and the transparent metal oxide may be ITO, IZO, ZnO, ITZO, Mo, or Ti.

When second electrode EL2 is the transflective electrode, second electrode EL2 may include Ag, Mg, Al, Pt, Pd, Au, Ni, Nd, Ir, Cr, Li, Ca, LiF/Ca, LiF/Al, Mo, Ti, or compounds or mixtures thereof (e.g., a mixture of Ag and Mg). Alternatively, second electrode EL2 may have a multi-layered structure including a reflective or transflective film made of the above materials and a transparent conductive film made of ITO, IZO, ZnO, or ITZO, or the like.

Second electrode EL2 may be made of Ag. Second electrode EL2 may further include Mg. In this case, when the amount of Ag included in second electrode EL2 is greater than the amount of Mg in second electrode EL2, transmittance of second electrode EL2 may be improved, and thus luminous efficiency of organic light emitting device OEL may be further improved.

Organic light emitting device OEL may be a top-emission type. First electrode EL1 may be a reflective electrode, and second electrode EL2 may be a transmissive or transflective electrode.

In organic light emitting device OEL according to an exemplary embodiment, as voltage is applied to each of first and second electrodes EL1 and EL2, holes injected from first electrode EL1 are transported to light emission layer EML via hole transport region HTR, and electrons injected from second electrode EL2 are transported to light emission layer EML via electron transport region ETR. Electrons and holes are recombined in light emission layer EML to generate excitons, and light is emitted during the excitons fall from an exited state to a ground state.

The organic capping layer is provided on second electrode EL2. Organic capping layer CPL may reflect the light emitted from light emission layer EML, from a top surface of organic capping layer CPL toward light emission layer EML. The reflected light may be amplified by a resonance effect in the organic layer to increase luminous efficiency of organic light emitting device OEL. In a top-emitting organic light emitting device, organic capping layer CPL may prevent a loss of light from the second electrode through total reflection of light.

Organic capping layer CPL includes an anthracene-based compound. Organic capping layer CPL may include a compound expressed by Chemical Formula 1 below:

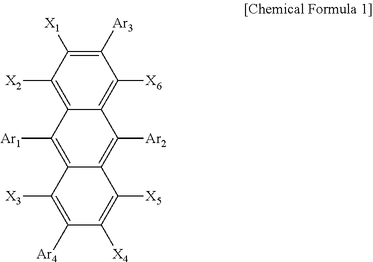

where, X₁ to X₆ are independently selected from the group consisting of hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁₋₆₀ alkyl group, a substituted or unsubstituted C₂₋₆₀ alkenyl group, a substituted or unsubstituted C₂₋₆₀ alkynyl group, a substituted or unsubstituted C₁₋₆₀ alkoxy group, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, a substituted or unsubstituted C₆₋₆₀ aryloxy group, a substituted or unsubstituted C₆₋₆₀ arylthio group, a substituted or unsubstituted C₂₋₆₀ heteroaryl group, —N(Q₁)(Q₂), and —Si(Q₃)(Q₄)(Q₅), wherein Q₁ to Q₅ are independently selected from the group consisting of hydrogen, a C₁₋₆₀ alkyl group, a C₆₋₂₀ aryl group, and a C₂₋₂₀ heteroaryl group; and Ar₁ to Ar₄ are independently selected from the group consisting of hydrogen, deuterium, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, and a substituted or unsubstituted C₂₋₆₀ heteroaryl group.

At least one of Ar₁ to Ar₄ may be expressed by Chemical Formula 2 below:

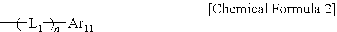

where, L₁ is selected from the group consisting of a substituted or unsubstituted C₃₋₁₀ cycloalkylene group, a substituted or unsubstituted C₃₋₁₀ cycloalkenylene group, a substituted or unsubstituted C₃₋₁₀ heterocycloalkylene group, a substituted or unsubstituted C₃₋₁₀ heterocycloalkenylene group, a substituted or unsubstituted C₆₋₆₀ arylene group, and a substituted or unsubstituted C₂₋₆₀ heteroarylene group; Ar₁₁ is selected from the group consisting of a substituted or unsubstituted C₃₋₁₀ heterocycloalkyl group, a substituted or unsubstituted C₃₋₁₀ heterocycloalkenyl group, and a substituted or unsubstituted C₂₋₆₀ heteroaryl group; and n is an integer of 0 to 3.

Organic capping layer CPL may have a refractive index of about 1.9 to about 2.4. When the refractive index organic capping layer CPL is less than about 1.9, the light emitted from light emission layer EML may not be sufficiently reflected from the top surface of organic capping layer CPL toward light emission layer EML, thereby reducing the amount of light which may be amplified by the resonance effect in the organic layer. Accordingly, luminous efficiency of organic light emitting device OEL may be lowered. On the contrary, when the refractive index organic capping layer CPL is greater than about 2.4, the light emitted from light emission layer EML may be excessively reflected from the top surface of organic capping layer CPL toward light emission layer EML, thereby leading to a decrease in the amount of light which may pass through organic capping layer CPL and display images.

Referring to FIGS. 1 and 2, organic capping layer CPL may include first organic capping layer CPL1 and second organic capping layer CPL2.

First organic capping layer CPL1 is provided on second electrode EL2. First organic capping layer CPL1 has a first refractive index. The first refractive index may be about 1.9 to about 2.4.

Second organic capping layer CPL2 is provided on first organic capping layer CPL1. Second organic capping layer CPL2 has a second refractive index. The second refractive index is greater than the first refractive index and, thus, light emitted from light emission layer EML may be reflected toward light emission layer EML from a top surface of first organic capping layer CPL1 and the interface between first and second organic capping layers CPL1 and CPL2. The second refractive index may be about 1.9 to about 2.4.

An organic light emitting device according to an exemplary embodiment may include an organic capping layer having a high refractive index, a first electrode which is a reflective electrode, and a second electrode which is a transmissive or transflective electrode, and thus may sufficiently reflect the light emitted from the light emission layer, from the top surface of the organic capping layer toward the light emission layer. The reflected light may be amplified by a resonance effect in the organic layer, so that an organic light emitting device may have high luminous efficiency. Therefore, an organic light emitting device according to an exemplary embodiment may achieve high efficiency and long life.

Hereinafter, a display device according to an exemplary embodiment will be described. Differences between the display device and the above-described organic light emitting device OEL will be mainly described, and the undescribed parts conform to the above-described organic light emitting device OEL.

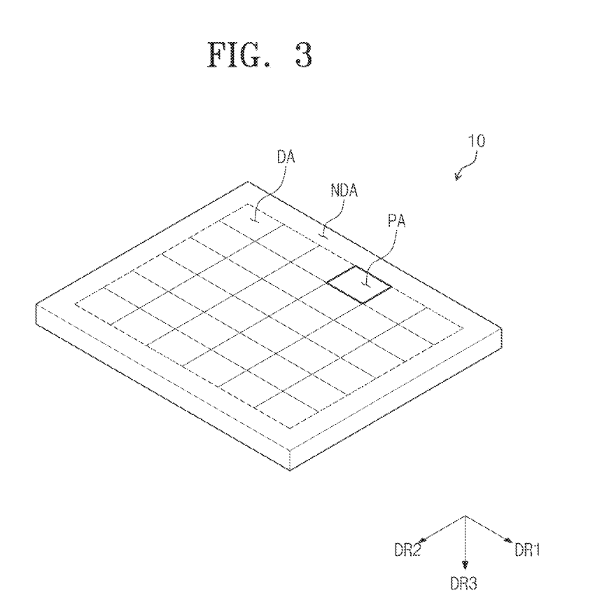

Referring to FIG. 3, display device 10 according to an exemplary embodiment includes a display area DA and a non-display area NDA.

Display area DA may display an image. Although not limited thereto, display area DA may have roughly a rectangular shape when it is seen in a thickness direction (e.g., DR3) of display device 10.

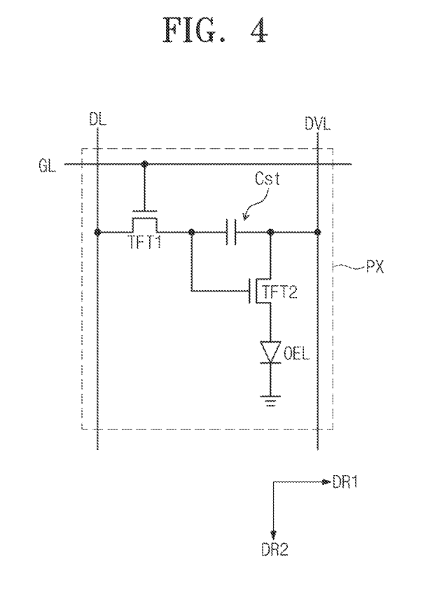

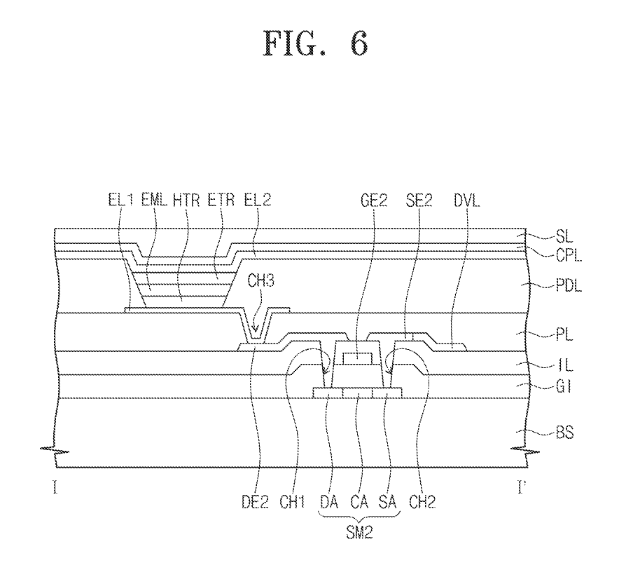

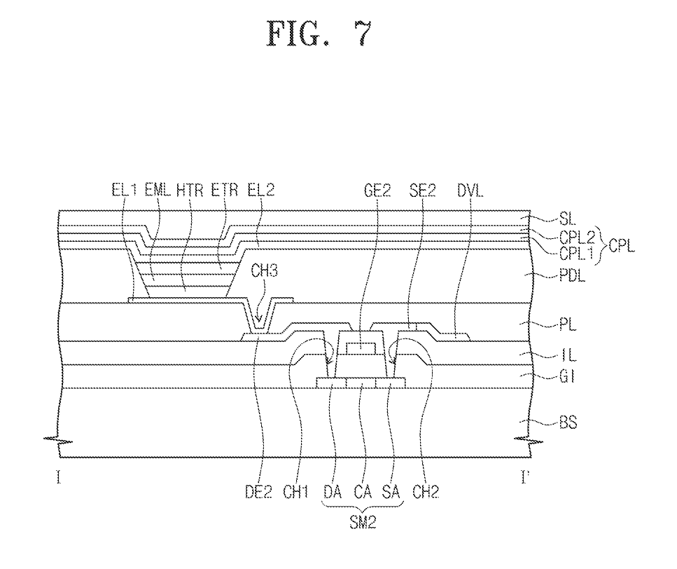

Display area DA includes a plurality of pixel areas (PAs). The pixel areas PAs may be disposed in the form of a matrix. The pixel areas PAs may be defined by a pixel defined layer (PDL in FIG. 6). The pixel areas PAs may include each of the plurality of pixels (PX in FIG. 4).

Non-display area NDA does not display any image. Non-display area NDA may surround display area DA when it is seen in the thickness direction (DR3) of display device 10. Non-display area NDA may be adjacent to display area DA along a first direction (e.g., DR1) and a second direction (e.g., DR2) which intersects with the first direction (e.g., DR1).

Referring to FIGS. 4 through 6, each of the pixels PXs includes a wiring unit which includes gate line GL, data line DL and driving voltage line DVL, thin film transistors TFT1 and TFT2 which are connected to the wiring unit, and an organic light emitting device OEL and a capacitor Cst which are connected to thin film transistors TFT1 and TFT2.

Each of the pixels PXs may emit light having a specific color, such as one of red light, green light, or blue light. The kind of colored light is not limited to the above, but may further include cyan light, magenta light, or yellow light.

Gate line GL extends in a first direction DR1. Data line DL extends in second direction DR2 which intersects with gate line GL. Driving voltage line DVL extends in substantially the same direction as data line DL. Gate line GL transfers a scanning signal to thin film transistors TFT1 and TFT2, data line DL transfers a data signal to thin film transistors TFT1 and TFT2, and the driving voltage line DVL provides a driving voltage to thin film transistors TFT1 and TFT2.

Thin film transistors TFT1 and TFT2 may include driving thin film transistor TFT2 for controlling organic light emitting device OEL, and switching thin film transistor TFT1 which switches driving thin film transistor TFT2. In an exemplary embodiment, each of the pixels PXs is described as including two thin film transistors TFT1 and TFT2, but is not limited thereto. According to one or more exemplary embodiments, each of the pixels PXs may include a thin film transistor and a capacitor, or may include three or more thin film transistors and two or more capacitors.

Switching thin film transistor TFT1 includes first gate electrode GE1, first source electrode SE1, and first drain electrode DE1. First gate electrode GE1 is connected to gate line GL, and first source electrode SE1 is connected to data line DL. First drain electrode DE1 is connected to first common electrode CE1 via a fifth contact hole CH5. Switching thin film transistor TFT1 transfers the data signal which is applied to data line DL, to driving thin film transistor TFT2 according to the scanning signal applied to gate line GL.

Driving thin film transistor TFT2 includes a second gate electrode GE2, second source electrode SE2, and second drain electrode DE2. Second gate electrode GE2 is connected to first common electrode CE1. Second source electrode SE2 is connected to driving voltage line DVL. Second drain electrode DE2 is connected to first electrode EL1 via a third contact hole CH3.

First electrode EL1 is connected to second drain electrode DE2 of driving thin film transistor TFT2. A common voltage is applied to second electrode EL2, and light emission layer EML emits light, for example, blue light, according to an output signal of driving thin film transistor TFT2, thus displaying an image.

Capacitor Cst is connected between second gate electrode GE2 and second source electrode SE2 of driving thin film transistor TFT2, and charges and keeps a data signal which is sent to second gate electrode GE2 of driving thin film transistor TFT2. Capacitor Cst may include first common electrode CE1 which is connected to first drain electrode DE1 via sixth contact hole CH6 and second common electrode CE2 which is connected to driving voltage line DVL.

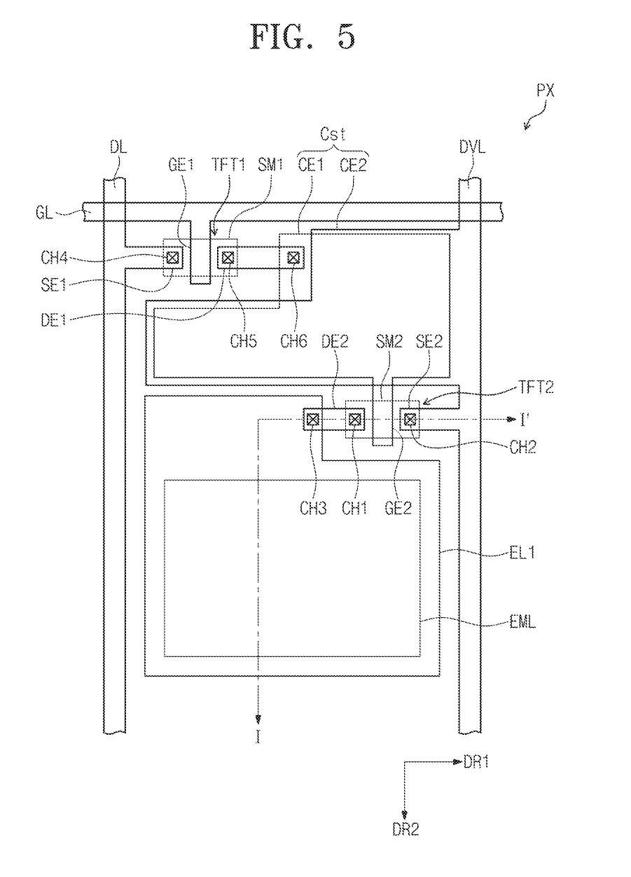

Referring to FIGS. 5 and 6, display device 10 includes a base substrate BS on which the thin film transistor and the organic light emitting device are stacked. The base substrate BS may be made of a material which is generally used, such as an insulating material (e.g., glass, plastic, or crystal). Examples of an organic polymer used for the base substrate BS may include polyethylene terephthalate (PET), polyethylene naphthalate (PEN), polyimide, and polyetersulfone. The base substrate BS may be selected after considering the material's mechanical strength, thermal stability, transparency, surface smoothness, ease of handling, water resistance, and the like.

A substrate buffer layer (not shown) may be provided on the base substrate BS. The substrate buffer layer prevents impurities from diffusing to switching thin film transistor TFT1 and driving thin film transistor TFT2. The substrate buffer layer may be made of silicon nitride (SiNₓ), silicon oxide (SiOₓ), or silicon oxinitride (SiOₓNy), but may be optional depending on materials of the base substrate and process conditions.

First and second semiconductor layers SM1 and SM2 are provided on the base substrate BS. First and second semiconductor layers SM1 and SM2 are made of semiconductor materials, and act as active layers of switching thin film transistor TFT1 and driving thin film transistor TFT2, respectively. First and second semiconductor layers SM1 and SM2 each includes source area SA, drain area DA, and channel area CA which is provided between source area SA and drain area DA. First and second semiconductor layers SM1 and SM2 each may be made of a material selected from the group consisting of inorganic semiconductors and organic semiconductors. Source area SA and drain area DA may be doped with n-type impurities or p-type impurities.

Gate insulating layer GI is provided on first and second semiconductor layers SM1 and SM2. Gate insulating layer GI covers first and second semiconductor layers SM1 and SM2. Gate insulating layer GI may be made of an organic insulating material or an inorganic insulating material.

First and second gate electrodes GE1 and GE2 are provided on the gate insulating layer GI. First and second gate electrodes GE1 and GE2 are provided to cover areas corresponding to channel areas CAs of first and second semiconductor layers SM1 and SM2, respectively.

Interlayer insulating layer IL is provided on first and second gate electrodes GE1 and GE2. Interlayer insulating layer IL covers the first and second gate electrodes GE1 and GE2. Interlayer insulating layer IL may be made of an organic insulating material or an inorganic insulating material.

First source electrode SE1 and first drain electrode DE1, and second source electrode SE2 and second drain electrode DE2 are provided on the interlayer insulating layer IL. Second drain electrode DE2 contacts drain area DA of second semiconductor layer SM2 via first contact hole CH1 which is provided on gate insulating layer GI and interlayer insulating layer IL. Second source electrode SE2 contacts source area SA of second semiconductor layer SM2 via second contact hole CH2 which is provided on gate insulating layer GI and interlayer insulating layer IL. First source electrode SE1 contacts source area (not shown) of the first semiconductor layer SM1 via fourth contact hole CH4 which is provided on gate insulating layer GI and interlayer insulating layer IL. First drain electrode DE1 contacts a drain area (not shown) of first semiconductor layer SM1 via fifth contact hole CH5 which is provided on gate insulating layer GI and interlayer insulating layer IL.

Passivation layer PL is provided on first source electrode SE1 and first drain electrode DE1, and on second source electrode SE2 and second drain electrode DE2. Passivation layer PL may act as a protective film which protects switching thin film transistor TFT1 and driving thin film transistor TFT2, and may act as a flattening film which makes top surfaces thereof flat.

First electrode EL1 is provided on passivation layer PL. First electrode EL1 may be an anode, and may be connected to second drain electrode DE2 of driving thin film transistor TFT2 via third contact hole CH3 which is provided on passivation layer PL.

On passivation layer PL, pixel defined layer PDL is provided in which pixel areas (PAs in FIG. 3) are defined to correspond to each of the pixels PXs. Pixel defined layer PDL exposes a top surface of first electrode EL1, and protrudes from base substrate BS along the perimeter of each of pixels PXs. Although not limited, pixel defined layer PDL may include a metal-fluorine ionic compound. For example, pixel defined layer PDL may be made of any one metal-fluorine ionic compound selected from the group consisting of LiF, BaF₂, and CsF. When the metal-fluorine ionic compound has a predetermined thickness, it has an insulating property. The thickness of pixel defined layer PDL may be about 10 nm to about 100 nm.

Organic light emitting device OEL is provided on each of the pixel areas (PA in FIG. 3) surrounded by the pixel defined layer PDL. Organic light emitting device OEL includes first electrode EL1, hole transport region HTR, light emission layer EML, electron transport region ETR, second electrode EL2, and organic capping layer CPL.

First electrode EL1 is conductive, and may be a pixel electrode or an anode. First electrode EL1 may be a transmissive electrode, transflective electrode, or reflective electrode. When first electrode EL1 is a transmissive electrode, first electrode EL1 may be made of transparent metal oxide such as indium tin oxide (ITO), indium zinc oxide (IZO), zinc oxide (ZnO), or indium tin zinc oxide (ITZO). When first electrode EL1 is a transflective electrode or the reflective electrode, first electrode EL1 may include Ag, Mg, Al, Pt, Pd, Au, Ni, Nd, Ir, Cr, or a mixture thereof.

An organic layer may be disposed on first electrode EL1. The organic layer includes light emission layer EML. The organic layer may further include hole transport region HTR and electron transport region ETR.

Hole transport region HTR is provided on the first electrode EL1. Hole transport region HTR may include at least one of hole injection layer HIL, hole transport layer HTL, a buffer layer, or an electron blocking layer.

Hole transport region HTR may have a single layer made of a single material, a single layer made of a plurality of different materials, or a multi-layered structure having a plurality layers made of a plurality of different materials.

In exemplary embodiments, hole transport region HTR may have a single-layered structure made of a plurality of different materials or a multi-layered structure which is sequentially stacked from first electrode EL1, such as hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer, but is not limited thereto.

Hole transport region HTR may be provided using various methods such as vacuum deposition, spin coating, casting, Langmuir-Blodgett (LB), inkjet printing, laser printing, or laser induced thermal imaging (LITI).

When hole transport region HTR includes hole injection layer HIL, hole transport region HTR may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris {N,-(2-naphthyl)-N-phenylamino}-triphenylamine (2TNATA), poly(3,4-ethylenedioxythiophene)/poly(4-styrenesulfonate) (PEDOT/PSS), polyaniline/dodecylbenzenesulfonic acid (PANI/DBSA), polyaniline/Camphor sulfonicacid (PANI/CSA), or (polyaniline)/poly(4-styrenesulfonate) (PANI/PSS).

When hole transport region HTR includes hole transport layer HTL, hole transport region HTR may include a carbazole derivative such as N-phenylcarbazole or polyvinylcarbazole, a fluorine derivative, a triphenylamine derivative such as N,N′-bis(3-methylphenyl)-N,N′-diphenyl-[1,1-biphenyl]-4,4′-diamine (TPD) or 4,4′, 4″-tris(N-carbazolyl)triphenylamine (TCTA), N,N′-di(1-naphthyl)-N,N′-diphenylbenzidine (NPB), or 4,4′-cyclohexylidene bis[N,N-bis(4-methylphenyl)benzenamine](TAPC).

Hole transport region HTR may have a thickness of about 100 Å to about 10,000 Å, e.g., about 100 Å to about 1,000 Å. When hole transport region HTR includes both hole injection layer HIL and hole transport layer HTL, the hole injection layer HIL may have a thickness of about 100 Å to about 10,000 Å, e.g., about 100 Å to about 1,000 Å, and hole transport layer HTL may have a thickness of about 50 Å to about 2,000 Å, e.g., about 100 Å to about 1,500 Å. When the thicknesses of hole transport region HTR, hole injection layer HIL, and hole transport layer HTL fall within the above ranges, respectively, satisfactory hole transport characteristics may be obtained without a substantial increase in driving voltage.

Hole transport region HTR may further include a charge generation material for improving conductivity, in addition to the aforementioned materials. The charge generation material may be homogeneously or non-homogeneously dispersed in hole transport region HTR. The charge generation material may be a p-dopant. The p-dopant may be, but is not limited to, one of a quinone derivative, a metal oxide, or a cyano group-containing compound. Non-restrictive examples of the p-dopant may include a quinone derivative such as tetracyanoquinodimethane (TCNQ) or 2,3,5,6-tetrafluoro-tetracyanoquinodimethane (F4-TCNQ), and a metal oxide such as tungsten oxide or molybdenum oxide, but are not limited thereto.

Hole transport region HTR may include at least one of the buffer layer or the electron blocking layer, in addition to hole injection layer HIL and hole transport layer HTL. The buffer layer may compensate a resonance distance according to the wavelength of light emitted from light emission layer EML and thus serve to increase luminous efficiency. Materials included in hole transport region HTR may be used for materials included in the buffer layer. The electron blocking layer serves to prevent electrons from being injected from electron transport region ETR to hole transport region HTR.

Light emission layer EML is provided on hole transport region HTR. Light emission layer EML may have a single layer made of a single material, a single layer made of a plurality of different materials, or a multi-layered structure having a plurality layers made of a plurality of different materials.

Light emission layer EML may be provided using various methods such as vacuum deposition, spin coating, casting, Langmuir-Blodgett (LB), inkjet printing, laser printing, or laser induced thermal imaging (LITI).

Light emission layer EML may be made of generally available materials, such as materials emitting red light, green light, and blue light, and may include a fluorescent material or a phosphor. Also, light emission layer EML may include a host and a dopant.

Although not particularly limited, the host may employ a material which is generally used, such as tris(8-hydroxyquinolino)aluminum (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN).

When light emission layer EML emits red light, light emission layer EML may include a fluorescent material containing (tris(dibenzoylmethanato)phenanthoroline europium) (PBD:Eu(DBM)3(Phen)) or perylene. When light emission layer EML emits red light, the dopant included in light emission layer EML may be selected from the group consisting of a metal complex and an organometallic complex, such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr), and octaethylporphyrin platinum (PtOEP).

When light emission layer EML emits green light, light emission layer EML may include a fluorescent material containing tris(8-hydroxyquinolino)aluminum (Alq3). When light emission layer EML emits green light, the dopant included in light emission layer EML may be selected from the group consisting of a metal complex and an organometallic complex such as fac-tris(2-phenylpyridine)iridium (Ir(ppy)3).

When light emission layer EML emits blue light, light emission layer EML may include a fluorescent material containing any one selected from the group consisting of spiro-DPVBi, spiro-6P, distyryl-benzene (DSB), distyryl-arylene (DSA), a polyfluorene (PFO) based polymer, and a poly(p-phenylene vinylene) (PPV) based polymer. When light emission layer EML emits blue light, the dopant included in light emission layer EML may be selected from the group consisting of a metal complex and an organometallic complex such as (4,6-F2ppy)2Irpic.

Electron transport region ETR is provided on light emission layer EML. Electron transport region ETR may include, but is not limited to, at least one of a hole blocking layer, an electron transport layer, or an electron injection layer.

Electron transport region ETR may have a multi-layered structure which is sequentially stacked from light emission layer EML, such as electron transport layer/electron injection layer or hole blocking layer/electron transport layer/electron injection layer, or have a single-layered structure in which at least two of the above layers are mixed.

Electron transport region ETR may be provided using various methods such as vacuum deposition, spin coating, casting, Langmuir-Blodgett (LB), inkjet printing, laser printing, or laser induced thermal imaging (LITI).

When electron transport region ETR includes the electron transport layer, electron transport region ETR may include tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), or mixtures thereof, but is not limited thereto. Electron transport layer ETR may have a thickness of about 100 Å to about 1,000 Å, e.g., about 150 Å to about 500 Å. When thickness of the electron transport layer falls within the above range, satisfactory electron transport characteristics may be obtained without a substantial increase in driving voltage.

When electron transport region ETR includes the electron injection layer, electron transport region ETR may use LiF, LiQ, Li₂O, BaO, NaCl, CsF, lanthanoide such as Yb, or a metal halide such as RbCl or RbI, but is not limited thereto. The electron injection layer may be also made of a mixture of an electron-transporting material and an insulating organo metal salt. The organo metal salt may have an energy band gap of about 4 eV or more. Specifically, the organo metal salt may include metal acetate, metal benzoate, metal acetoacetate, metal acetylacetonate, or metal stearate. The electron injection layer may have a thickness of about 1 Å to about 100 Å, e.g., about 3 Å to about 90 Å. When the thickness of the electron injection layer falls within the above range, satisfactory electron injection characteristics may be obtained without a substantial increase in driving voltage.

As mentioned above, electron transport region ETR may include the hole blocking layer. The hole blocking layer may include at least one of 2,9-dimethyl-4,7-diphenyl-1,10-phenanthroline (BCP) or 4,7-diphenyl-1,10-phenanthroline (Bphen), but is not limited thereto. The hole blocking layer may have a thickness of about 20 Å to about 1,000 Å, such as about 30 Å to about 300 Å. When the thickness of the hole blocking layer falls within the above range, satisfactory hole blocking characteristics may be obtained without a substantial increase in driving voltage.

Second electrode EL2 is provided on the organic layer. Second electrode EL2 may be a common electrode or a cathode. Second electrode EL2 may be a transmissive electrode or transflective electrode.

When second electrode EL2 is a transmissive electrode, second electrode EL2 may include Li, Ca, LiF/Ca, LiF/Al, Al, Mg, BaF, Ba, Ag, or compounds or mixtures thereof (e.g., a mixture of Ag and Mg). Second electrode EL2 may include an auxiliary electrode. The auxiliary electrode may include a film, and a transparent metal oxide on the film. The film may be formed in such a way that the above-described material is deposited to face light emission layer EML, and the transparent metal oxide may be ITO, IZO, ZnO, ITZO, Mo, or Ti.

When second electrode EL2 is a transflective electrode, second electrode EL2 may include Ag, Mg, Al, Pt, Pd, Au, Ni, Nd, Ir, Cr, Li, Ca, LiF/Ca, LiF/Al, Mo, Ti, or compounds or mixtures thereof (e.g., a mixture of Ag and Mg). Alternatively, second electrode EL2 may have a multi-layered structure including a reflective or transflective film made of the above materials and a transparent conductive film made of ITO, IZO, ZnO, or ITZO, or the like.

Second electrode EL2 may be made of Ag, and second electrode EL2 may further include Mg. In this case, when the amount of Ag included in second electrode EL2 is greater than the amount of Mg in second electrode EL2, transmittance of second electrode EL2 may be improved, and thus luminous efficiency of organic light emitting device OEL may be further improved.

Organic light emitting device OEL may be a top-emission type. First electrode EL1 may be a reflective electrode, and second electrode EL2 may be a transmissive or transflective electrode.

In display device 10, according to one or more exemplary embodiments, when voltage is applied to each of first and second electrodes EL1 and EL2, holes injected from first electrode EL1 are transported to light emission layer EML via hole transport region HTR, and electrons injected from second electrode EL2 are transported to light emission layer EML via electron transport region ETR. Electrons and holes are recombined in light emission layer EML to generate excitons, and light is emitted during the excitons fall from an excited state to a ground state.

The organic capping layer is provided on second electrode EL2. Organic capping layer CPL may reflect the light emitted from light emission layer EML, from a top surface of organic capping layer CPL toward light emission layer EML. The reflected light may be amplified by a resonance effect in the organic layer to increase luminous efficiency of display device 10. In a top-emitting organic light emitting device, organic capping layer CPL may prevent a loss of light from the second electrode through total reflection of light.

Organic capping layer CPL includes an anthracene-based compound. Organic capping layer CLP may include a compound expressed by Chemical Formula 1 below:

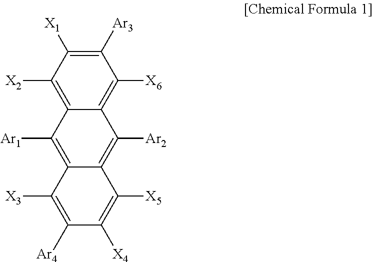

where, X₁ to X₆ are independently selected from the group consisting of hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁₋₆₀ alkyl group, a substituted or unsubstituted C₂₋₆₀ alkenyl group, a substituted or unsubstituted C₂₋₆₀ alkynyl group, a substituted or unsubstituted C₁₋₆₀ alkoxy group, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, a substituted or unsubstituted C₆₋₆₀ aryloxy group, a substituted or unsubstituted C₆₋₆₀ arylthio group, a substituted or unsubstituted C₂₋₆₀ heteroaryl group, —N(Q₁)(Q₂), and —Si(Q₃)(Q₄)(Q₅), wherein Q₁ to Q₅ are independently selected from the group consisting of hydrogen, a C₁₋₆₀ alkyl group, a C₆₋₂₀ aryl group, and a C₂₋₂₀ heteroaryl group; and Ar₁ to Ar₄ are independently selected from the group consisting of hydrogen, deuterium, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, and a substituted or unsubstituted C₂₋₆₀ heteroaryl group.

At least one of the Ar₁ through Ar₄ may be expressed by Chemical Formula 2 below:

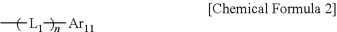

where, L₁ is selected from the group consisting of a substituted or unsubstituted C₃₋₁₀ cycloalkylene group, a substituted or unsubstituted C₃₋₁₀ cycloalkenylene group, a substituted or unsubstituted C₃₋₁₀ heterocycloalkylene group, a substituted or unsubstituted C₃₋₁₀ heterocycloalkenylene group, a substituted or unsubstituted C₆₋₆₀ arylene group, and a substituted or unsubstituted C₂₋₆₀ heteroarylene group; Ar₁₁ is selected from the group consisting of a substituted or unsubstituted C₃₋₁₀ heterocycloalkyl group, a substituted or unsubstituted C₃₋₁₀ heterocycloalkenyl group, and a substituted or unsubstituted C₂₋₆₀ heteroaryl group; and n is an integer of 0 to 3.

Organic capping layer CPL may have a refractive index of about 1.9 to about 2.4. When the refractive index organic capping layer CPL is less than about 1.9, the light emitted from light emission layer EML may not be sufficiently reflected from the top surface of organic capping layer CPL toward light emission layer EML, thereby reducing the amount of light which may be amplified by the resonance effect in the organic layer. Accordingly, luminous efficiency of organic light emitting device OEL may be lowered. On the contrary, when the refractive index organic capping layer CPL is greater than about 2.4, the light emitted from light emission layer EML may be excessively reflected from the top surface of organic capping layer CPL toward light emission layer EML, thereby leading to a decrease in the amount of light which may pass through organic capping layer CPL and display images.

Sealing layer SL is provided which covers organic capping layer CPL and second electrode EL2. Sealing layer SL may include at least one of an organic layer or an inorganic layer. Sealing layer SL protects organic light emitting device OEL.

Referring to FIGS. 4, 5, and 7, organic capping layer CPL may include first organic capping layer CPL1 and second organic capping layer CPL2.

First organic capping layer CPL1 is provided on second electrode EL2. First organic capping layer CPL1 has a first refractive index. The first refractive index may be about 1.9 to about 2.4.

Second organic capping layer CPL2 is provided on first organic capping layer CPL1. Second organic capping layer CPL2 has a second refractive index. The second refractive index is greater than the first refractive index, and thus the light emitted from light emission layer EML may be reflected from a top surface of first organic capping layer CPL1 and the interface between the first and second organic capping layers CPL1 and CPL2 toward light emission layer EML. The second refractive index may be about 1.9 to about 2.4.

Exemplary embodiments include an organic capping layer having a high refractive index, a first electrode which is a reflective electrode, and a second electrode which is a transmissive or transflective electrode, and thus may sufficiently reflect the light emitted from the light emission layer, from the top surface of the organic capping layer toward the light emission layer. The reflected light may be amplified by a resonance effect in the organic layer, so that a display device may have high luminous efficiency. Therefore, a display device according to an exemplary embodiment may achieve high efficiency and long lifetime.

Hereinafter, the present disclosure will be described more specifically through specific Examples. Examples below are intended to facilitate understanding of the present disclosure, but the scope of the present disclosure should not be limited thereto.

### Example 1

On a glass substrate, a reflective film of a first electrode is formed of Al, and indium tin oxide (ITO) was deposited on the top surface of the reflective film which is made of Al. As organic film layers on the ITO, m-TDATA are deposited to provide a hole injection layer, NPB is deposited to provide a hole transport layer, red color-CBP:BTPIr, green color-CBP:Ir(ppy)3 and blue color-Alq3:DPBVi are deposited to provide a light emission layer, Alq3 is deposited to provide an electron transport layer, and LiF is deposited to provide an electron injection layer. Ag and Mg are deposited at a ratio of 1:9 to provide a second electrode. Using a vacuum deposition method, anthracene is deposited to provide an organic capping layer having a thickness of 200 Å.

### Example 2

The same procedures above are performed, except that Ag and Mg are deposited at a ratio of 9:1 to provide a second electrode.

### Comparative Example 1

The same procedures as Example 1 were performed except that a compound expressed by Chemical Formula 3 below was used instead of anthracene to provide an organic capping layer.

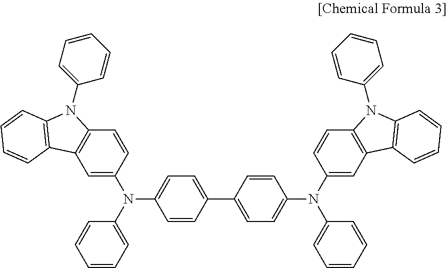 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Comparative Example 2

The same procedures as Example 2 were performed except that a compound expressed by Chemical Formula 3 above was used instead of anthracene to provide an organic capping layer.

Experimental Results

Current efficiencies were measured for 1 and 2, and Comparative Examples 1 and 2. Current efficiencies of organic light emitting devices were measured during operation at a current density of 10 mA/cm².

TABLE 1

| | Color of light emitted | |
|---|---|---|
| | from the light emission | |
| | layer | Efficiency (cd/A) |
| Example 1 | Red | 42.5 |
| | Green | 74.9 |
| | Blue | 5.5 |
| Comparative Example 1 | Red | 39.7 |
| | Green | 73.5 |
| | Blue | 4.7 |
| Example 2 | Red | 49.0 |
| | Green | 92.5 |
| | Blue | 6.8 |
| Comparative Example 2 | Red | 41.3 |
| | Green | 81.9 |
| | Blue | 5.8 |

Referring Table 1 above, it could be found that the organic light emitting device in Example 1 had higher efficiency than the organic light emitting device in Comparative Example 1, and the organic light emitting device in Example 2 had higher efficiency than the organic light emitting device in Comparative Example 2.

An organic light emitting device according to an exemplary embodiment may enhance efficiency and prolong lifetime.

A display device according to an exemplary embodiment may enhance efficiency and prolong lifetime.

Although certain exemplary embodiments and implementations have been described herein, other embodiments and modifications will be apparent from this description. Accordingly, the present disclosure is not limited to such embodiments, but rather to the broader scope of the presented claims and various obvious modifications and equivalent arrangements.

What is claimed is:

1. An organic light emitting device, comprising:
a first electrode;
a hole transport region disposed on the first electrode;
a light emission layer disposed on the hole transport region;
an electron transport region disposed on the light emission layer;
a second electrode disposed on the electron transport region; and
an organic capping layer disposed on the second electrode,
wherein the organic capping layer comprises an anthracene-based compound.

2. The organic light emitting device of claim 1, wherein the organic capping layer comprises a compound expressed by Chemical Formula 1 below. 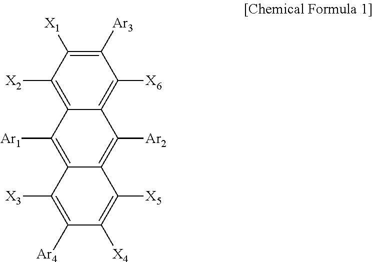
where, X₁ to X₆ are independently selected from the group consisting of hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁₋₆₀ alkyl group, a substituted or unsubstituted C₂₋₆₀ alkenyl group, a substituted or unsubstituted C₂₋₆₀ alkynyl group, a substituted or unsubstituted C₁₋₆₀ alkoxy group, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, a substituted or unsubstituted C₆₋₆₀ aryloxy group, a substituted or unsubstituted C₆₋₆₀ arylthio group, a substituted or unsubstituted C₂₋₆₀ heteroaryl group, —N(Q₁)(Q₂), and —Si(Q₃)(Q₄)(Q₅), wherein Q₁ to Q₅ are independently selected from the group consisting of hydrogen, a C₁₋₆₀ alkyl group, a C₆₋₂₀ aryl group, and a C₂₋₂₀ heteroaryl group; and
Ar₁ to Ar₄ are independently selected from the group consisting of hydrogen, deuterium, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, and a substituted or unsubstituted C₂₋₆₀ heteroaryl group.

3. The organic light emitting device of claim 2, wherein at least one of the Ar₁ to Ar₄ is expressed by Chemical Formula 2 below. 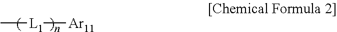
where, L₁ is selected from the group consisting of a substituted or unsubstituted C₃₋₁₀ cycloalkylene group, a substituted or unsubstituted C₃₋₁₀ cycloalkenylene group, a substituted or unsubstituted C₃₋₁₀ heterocycloalkylene group, a substituted or unsubstituted C₃₋₁₀ heterocycloalkenylene group, a substituted or unsubstituted C₆₋₆₀ arylene group, and a substituted or unsubstituted C₂₋₆₀ heteroarylene group;
Ar₁₁ is selected from the group consisting of a substituted or unsubstituted C₃₋₁₀ heterocycloalkyl group, a substituted or unsubstituted C₃₋₁₀ heterocycloalkenyl group, and a substituted or unsubstituted C₂₋₆₀ heteroaryl group; and
n is an integer of 0 to 3.

4. The organic light emitting device of claim 1, wherein the organic capping layer has a refractive index of about 1.9 to about 2.4.

5. The organic light emitting device of claim 1, wherein the organic capping layer comprises:
a first organic capping layer having a first refractive index; and
a second organic capping layer which is disposed on the first organic capping layer and has a second refractive index greater than the first refractive index.

6. The organic light emitting device of claim 5, wherein each of the first and second refractive indices is about 1.9 to about 2.4.

7. The organic light emitting device of claim 1, wherein the first electrode is a reflective electrode and the second electrode is one of a transmissive electrode and a transflective electrode.

8. The organic light emitting device of claim 1, wherein the electron transport region comprises at least one material selected from the group consisting of LiF, Lithium quinolate (LiQ), Li₂O, BaO, NaCl, CsF, Yb, RbCl, and RbI.

9. The organic light emitting device of claim 1, wherein the second electrode comprises Ag, Mg, Al, Pt, Pd, Au, Ni, Nd, Ir, Cr, Li, Ca, LiF/Ca, LiF/Al, Mo, Ti, or compounds or mixtures thereof.

10. A display device, comprising pixels, wherein,
at least one of the pixels comprises:
a first electrode;
a hole transport region disposed on the first electrode;
a light emission layer disposed on the hole transport region;
an electron transport region disposed on the light emission layer;
a second electrode disposed on the electron transport region; and
an organic capping layer disposed on the second electrode,
wherein the organic capping layer comprises an anthracene-based compound.

11. The display device of claim 10, wherein the organic capping layer comprises a compound expressed by Chemical Formula 1 below. 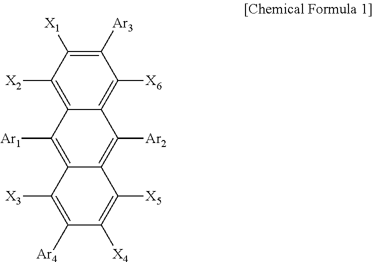
where, X₁ to X₆ are independently selected from the group consisting of hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a substituted or unsubstituted C₁₋₆₀ alkyl group, a substituted or unsubstituted C₂₋₆₀ alkenyl group, a substituted or unsubstituted C₂₋₆₀ alkynyl group, a substituted or unsubstituted C₁₋₆₀ alkoxy group, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, a substituted or unsubstituted C₆₋₆₀ aryloxy group, a substituted or unsubstituted C₆₋₆₀ arylthio group, a substituted or unsubstituted C₂₋₆₀ heteroaryl group, —N(Q₁)(Q₂), and —Si(Q₃)(Q₄)(Q₅), wherein Q₁ to Q₅ are independently selected from the group consisting of hydrogen, a C₁₋₆₀ alkyl group, a C₆₋₂₀ aryl group, and a C₂₋₂₀ heteroaryl group; and
Ar₁ to Ar₄ are independently selected from the group consisting of hydrogen, deuterium, a substituted or unsubstituted C₃₋₁₀ cycloalkyl group, a substituted or unsubstituted C₃₋₁₀ cycloalkenyl group, a substituted or unsubstituted C₃₋₁₀ heterocycloalkyl group, a substituted or unsubstituted C₃₋₁₀ heterocycloalkenyl group, a substituted or unsubstituted C₆₋₆₀ aryl group, and a substituted or unsubstituted C₂₋₆₀ heteroaryl group.

12. The display device of claim 11, wherein at least one of the Ar₁ to Ar₄ is expressed by Chemical Formula 2 below. 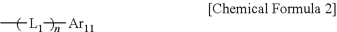
where, L₁ is selected from the group consisting of a substituted or unsubstituted C₃₋₁₀ cycloalkylene group, a substituted or unsubstituted C₃₋₁₀ cycloalkenylene group, a substituted or unsubstituted C₃₋₁₀ heterocycloalkylene group, a substituted or unsubstituted C₃₋₁₀ heterocycloalkenylene group, a substituted or unsubstituted C₆₋₆₀ arylene group, and a substituted or unsubstituted C₂₋₆₀ heteroarylene group;
Ar₁₁ is selected from the group consisting of a substituted or unsubstituted C₃₋₁₀ heterocycloalkyl group, a substituted or unsubstituted C₃₋₁₀ heterocycloalkenyl group, and a substituted or unsubstituted C₂₋₆₀ heteroaryl group; and
n is an integer of 0 to 3.

13. The display device of claim 10, wherein the organic capping layer has a refractive index of about 1.9 to about 2.4.

14. The display device of claim 10, wherein the organic capping layer comprises:
a first organic capping layer having a first refractive index; and
a second organic capping layer which is disposed on the first organic capping layer and has a second refractive index greater than the first refractive index.

15. The display device of claim 14, wherein each of the first and second refractive indices is about 1.9 to about 2.4.

16. The display device of claim 10, wherein the first electrode is a reflective electrode and the second electrode is one of a transmissive electrode and a transflective electrode.

17. The display device of claim 10, wherein the electron transport region comprises at least one material selected from the group consisting of LiF, LiQ, Li₂O, BaO, NaCl, CsF, Yb, RbCl, and RbI.

18. The display device of claim 10, wherein the second electrode comprises Ag, Mg, Al, Pt, Pd, Au, Ni, Nd, Ir, Cr, Li, Ca, LiF/Ca, LiF/Al, Mo, Ti, or compounds or mixtures thereof.
